(19) United States
(12) Patent Application Publication
(10) Pub. No.: US 2024/0255560 A1
(43) Pub. Date: Aug. 1, 2024

(54) CABLE FAULT DIAGNOSIS USING RECONSTRUCTED REFLECTION SIGNALS

(71) Applicant: Microchip Technology Incorporated, Chandler, AZ (US)

(72) Inventors: Jiachi Yu, Foshan (CN); Dixon Chen, Shenzhen (CN); Kevin Yang, Shenzhen (CN); Markus N. Becht, Marxzell (DE)

(21) Appl. No.: 18/424,125

(22) Filed: Jan. 26, 2024

(30) Foreign Application Priority Data
Jan. 28, 2023 (CN) 202310087738.5

(51) Int. Cl. G01R 31/11; G01R 31/08; G01R 31/52; G01R 31/58

(52) U.S. Cl. CPC G01R 31/11; G01R 31/083; G01R 31/088; G01R 31/52; G01R 31/58

(57) ABSTRACT

Cable fault detection using reconstructed reflection signals and related systems, methods, and devices are disclosed. An apparatus includes a terminal to provision and observe a signal on the cable and a processing circuitry. The processing circuitry may reconstruct a reflection signal at least partially responsive to the observed signal, generate correlation values between the reconstructed reflection signal and multiple signals representing the transmit signal as variably delayed; and determine whether a fault is present in the cable at least partially responsive to the correlation values.

### PRIORITY CLAIM

This application claims the benefit of the filing date of Chinese Patent Application Serial No. 202310087738.5, filed Jan. 28, 2023, for “CABLE FAULT DIAGNOSIS USING RECONSTRUCTED REFLECTION SIGNALS.”

### TECHNICAL FIELD

Examples of this disclosure relate generally to fault detection on a cable, and more specifically, signal acquisition, reconstruction, and correlation, and related systems, methods, and devices.

### BACKGROUND

Cables may function as electrical transmission lines that transmit power and/or information using electrical currents. If a conductor or insulation of a cable is damaged, a cable fault may occur. Cable faults typically include open-circuit faults and short-circuit faults. An open-circuit fault occurs where a break in the conductor prevents and/or attenuates transmission of electrical signals on the cable. A short-circuit fault may occur when two conductors of the cable come into contact with each other due to a failure in the insulation of the cable. Both open-circuit and short-circuit faults may degrade performance of a cable or render the cable useless.

### BRIEF DESCRIPTION OF THE DRAWINGS

While this disclosure concludes with claims particularly pointing out and distinctly claiming specific examples, various features and advantages of examples within the scope of this disclosure may be more readily ascertained from the following description when read in conjunction with the accompanying drawings, in which:

FIG. 1 is a functional block diagram of a network segment including a link layer device and a physical layer (PHY) device, according to some examples.

FIG. 2 is a block diagram of an example system that, in various examples, may be used to implement various functions, operations, acts, processes, and/or methods disclosed herein.

FIG. 3A is a plot illustrating generation of a digital representation of an observed signal, in accordance with one or more examples.

FIG. 3B is a plot illustrating generation of an energy detect (ED) signal from an observed signal, in accordance with one or more examples.

FIG. 4A is a signal timing diagram illustrating an idealized example of a construction of a reflection signal in real-world conditions, in accordance with some examples of the disclosure.

FIG. 4B is a signal timing diagram illustrating a more realistic example of a reconstruction of a reflection signal in real-world conditions, in accordance with some examples of the disclosure.

FIG. 5 is a flowchart depicting an example method of detecting faults in a cable, in accordance with some disclosed examples.

FIG. 6 is a signal correlation plot graphically illustrating a positive correlation between a transmit signal and a reconstructed reflection signal, in accordance with one or more examples.

FIG. 7 is a signal correlation plot that illustrates a negative correlation indicating a short-circuit fault, in accordance with one or more examples.

FIG. 8 is a signal correlation plot depicting results of performing a correlation multiple times, in accordance with one or more examples.

FIG. 9 is a flowchart illustrating a method for determining whether a fault is present on a cable, in accordance with one or more examples.

FIG. 10 is a flowchart illustrating a method of correlation.

FIG. 11 depicts a flowchart of a method of detecting fault type and location, including faults at zero meters from a transmitter of a signal, according to some examples.

FIG. 12 is a block diagram of an example device that, in various examples, may be used to implement various functions, operations, acts, processes, and/or methods disclosed herein.

### DETAILED DESCRIPTION

In the following detailed description, reference is made to the accompanying drawings, which form a part hereof, and in which are shown, by way of illustration, specific examples in which the present disclosure may be practiced. These examples are described in sufficient detail to enable a person of ordinary skill in the art to practice the present disclosure. However, other examples enabled herein may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. In some instances similar structures or components in the various drawings may retain the same or similar numbering for the convenience of the reader; however, the similarity in numbering does not necessarily mean that the structures or components are identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, steps, features, functions, or the like.

It will be readily understood that the components of the examples as generally described herein and illustrated in the drawings could be arranged and designed in a wide variety of different configurations. Thus, the following description of various examples is not intended to limit the scope of the present disclosure, but is merely representative of various examples. While the various aspects of the examples may be presented in the drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art will understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the examples disclosed herein may be implemented or performed with a general purpose processor, a special purpose processor, a digital signal processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer is to execute computing instructions (e.g., software code) related to examples of the present disclosure.

The examples may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, other structure, or combinations thereof. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may include one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

A cable may include a single wire or it may include several wires bundled together or twisted together.

As used herein, the terms “reflection” and “reflection signal” refer to a signal reconstructed by a processing circuitry of a transmitter using a received signal, which received signal is in response to a signal that is transmitted through the cable. A reflected signal may indicate where at least some of a transmitted signal is reflected back to the transmitter, possibly due to imperfections or discontinuities in the cable.

As used herein, the term “peak” refers to a point in a set of values represented by a curve, where the curve may depict a signal over time or over delay, wherein a magnitude value of the point is higher than magnitudes of those points or values on either side of the point. A “positive peak” means that a value of a peak in a curve is positive. A “negative peak” means that a value of a peak in a curve is negative.

Cables, such as network cables, function as electrical transmission lines that may carry power and/or information using electrical currents. A cable may include a single wire or it may include several wires bundled together or twisted together. If a cable's wiring or insulation is damaged, a cable fault may occur. Because cables are used extensively in modern technology devices, cable faults may create widespread problems. Moreover, cables are often laid underground or are routed through complex objects such as vehicles, making fault identification and repair costly and time-intensive. As such, it may be helpful to be able to swiftly and accurately identify a fault type and location in order to most efficiently find and repair/replace the faulty section of the cable.

Cable fault detection may include locating faults in a cable. One method of cable fault detection involves the use of a time-domain reflectometer (“TDR”). A TDR operates by transmitting a single pulse of energy along a cable. If the pulse sent by the TDR encounters a fault in the cable, at least some of the pulse will be reflected back to the transmitter. The TDR measures the reflection of the pulse and the propagation delay of the reflection between transmission of the pulse and reception of the pulse reflection to determine the type and location of the fault in the cable. The type and location of the fault may be determined using a lookup table that associates TDR measurements with type and/or location of faults in the cable. The associations in the lookup table may be predetermined by testing cables with known faults and associating the fault types and locations with the resulting TDR measurements. This method of fault detection, however, has several problems that make identifying a fault type (e.g., a short circuit or an open circuit) and location difficult. First, when a cable has imperfections along its length, or when the cable is being used as a shared transmission medium having multiple connections, reflections from an open circuit in the cable may become compromised due to the multiple connections in an unpredictable manner, such that the compromised reflections are difficult to interpret. Second, due to the complex loading conditions resulting from multiple connections to the cable, overshoot that occurs on a first pulse edge is hard to distinguish from the reflected signals resulting from the multiple connections, again creating ambiguity in the received reflected signal. If a fault is located near endpoints of the cable, pulse echoes, which are reflections from the endpoint of cables rather than from a fault located along the extent of the cable, may interfere with the reflections from the fault. The interference with the reflections from faults from the pulse echoes may cause problems accurate TDR measurements and may not yield reliable results.

Ethernet standards including 10BASE-TIS, a network technology specified in IEEE 802.3cg™, use a single twisted pair as a shared transmission medium. 10BASE-TIS uses a multidrop technology where each node in a network connects the shared transmission medium to a single cable. While systems employing 10BASE-TIS may use a TDR for fault type and location diagnosis, this diagnosis may be ambiguous due to the multidrop nature of the cable and the length of the cable, which may lead to attenuation of incident and reflected signals. A TDR also may fail to distinguish between near end and far end faults in the cable.

In accordance with various examples of the present disclosure, an apparatus may include a terminal to observe, responsive to provision of a transmit signal to a cable, a signal on the cable. The apparatus includes a processing circuitry to reconstruct a reflection signal at least partially responsive to the observed signal, and determine whether a fault is present in the cable at least partially responsive to a correlation between the reconstructed reflection signal and the transmit signal.

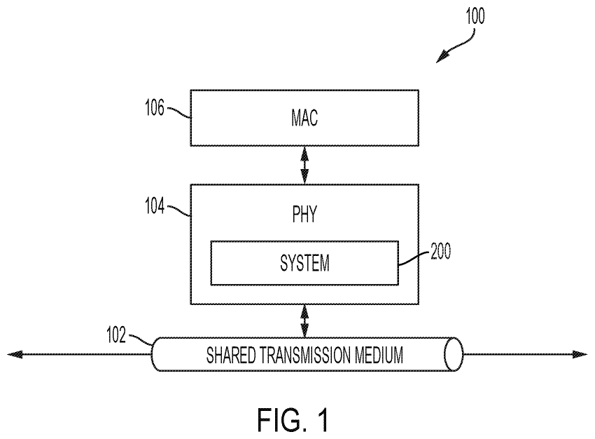

FIG. 1 is a functional block diagram of a network segment 100 including a link layer device, a MAC 106, and a physical layer (PHY) device, PHY 104, according to some examples. As non-limiting examples, network segment 100 may be a segment of a multi-drop network, a segment of a multi-drop sub-network, a segment of a mixed media network, or a combination thereof or sub combination thereof. As non-limiting examples, network segment 100 may be part of, or include one or more of, a microcontroller-type embedded system, a user-type computer, a computer server, a notebook computer, a tablet, a handheld device, a mobile device, a wireless earbud device or headphone device, a wired earbud or headphone device, an appliance sub-system, lighting sub-system, sound sub-system, building control systems, residential monitoring system (e.g., for security or utility usage, without limitation) system, elevator system or sub-system, public transit control system (e.g., for above ground train, below ground train, trolley, or bus, without limitation), an automobile system or automobile sub-system, or an industrial control system, without limitation.

PHY 104 may interface with MAC 106. As non-limiting examples, PHY 104 and/or MAC 106 may be respective chip packages including memory and/or logic for carrying out all or portions of examples described herein. As non-limiting examples, PHY 104 and MAC 106, respectively, may be implemented as separate chips or circuitry (e.g., integrated circuits) in a single chip package (e.g., a system-in-a-package (SIP)).

PHY 104 also interfaces with a shared transmission medium 102, which shared transmission medium 102 may be a physical medium that is a communication path for nodes that are part of network segment 100 or a network of which network segment 100 is a part, including nodes that include instances of PHY 104 and MAC 106. The shared transmission medium 102 may be a cable such as a network cable. As a non-limiting example, shared transmission medium 102 may be a single twisted pair such as used for single pair Ethernet, e.g., 10BASE-TIS. Faults (e.g., open circuits, short circuits) in the shared transmission medium 102 may be detected according to various examples disclosed herein.

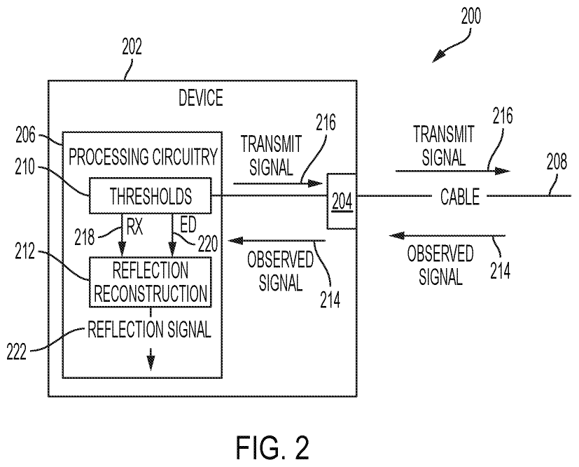

FIG. 2 is a block diagram of an example system 200 that, in various examples, may be used to implement various functions, operations, acts, processes, and/or methods disclosed herein. System 200 may include device 202, which may include processing circuitry 206 operably coupled to terminal 204. System 200 may include cable 208, which is operably coupled to terminal 204. Cable 208 may have faults that may be detected using examples described in this disclosure.

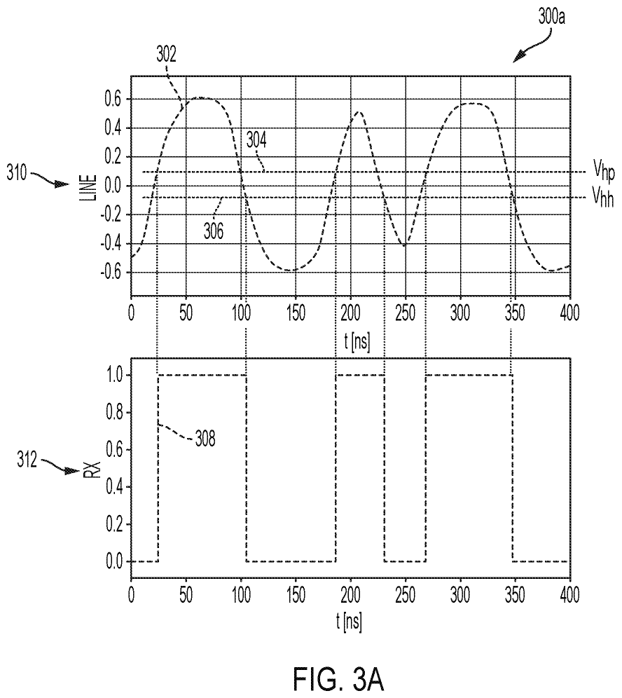

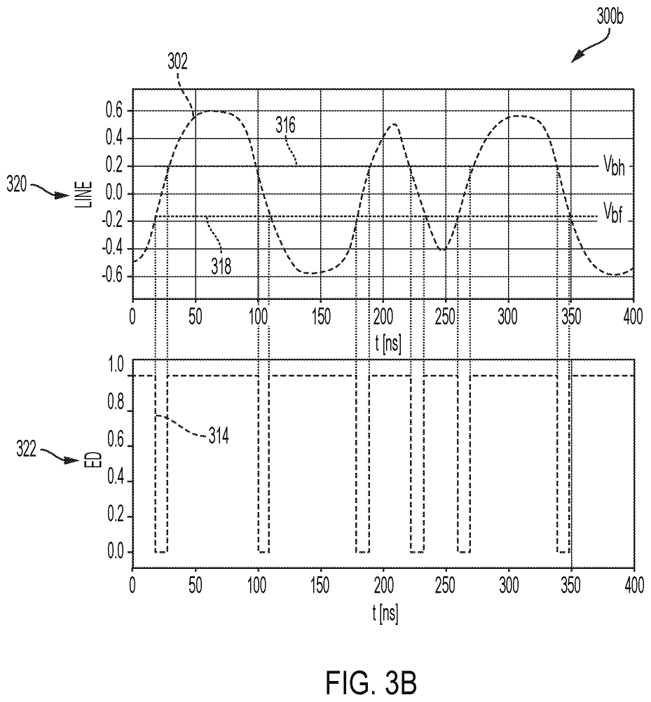

Processing circuitry 206 may also perform operations of examples disclosed herein. For example, processing circuitry 206 may manage transmission and processing of signals on cable 208 through terminal 204. Processing circuitry 206 may transmit or provide a transmit signal 216 to cable 208 and listen for, and observe, any observed signals 214. The transmit signal 216 may be a data packet sent over the cable 208 or it may be random data, i.e., random bits. Observed signals 214 may be processed by processing circuitry 206. The observed signals 214 may be respectively provided to thresholds circuitry 210, which outputs an RX signal 218 and an energy detect (ED) signal 220. Each of RX signal 218 and ED signal 220 exhibits predetermined signal levels responsive to amplitudes of observed signals 214. The threshold values used to generate RX signal 218 and ED signal 220 may be different. The thresholds and the determination of the RX signal 218 and ED signal 220 are discussed with more detail in reference to FIG. 3A and FIG. 3B.

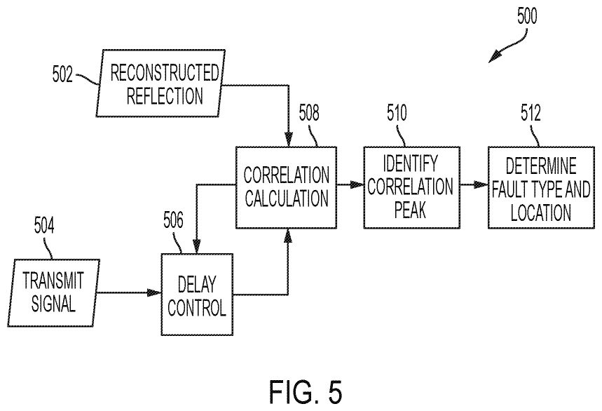

Reflection reconstruction 212 may reconstruct a reflection signal based on RX signal 218 and ED signal 220, which as indicated above are both extracted from the observed signal 214. The reconstructed reflection signal 222 may be compared and correlated to the original transmit signal 216. Processing circuitry 206 may perform analysis of the correlation between the transmit signal 216 and the reconstructed reflection signal 222 to determine whether a fault is present on cable 208, what type of fault is present, and a fault location along cable 208, as discussed with more details below with reference to FIG. 5.

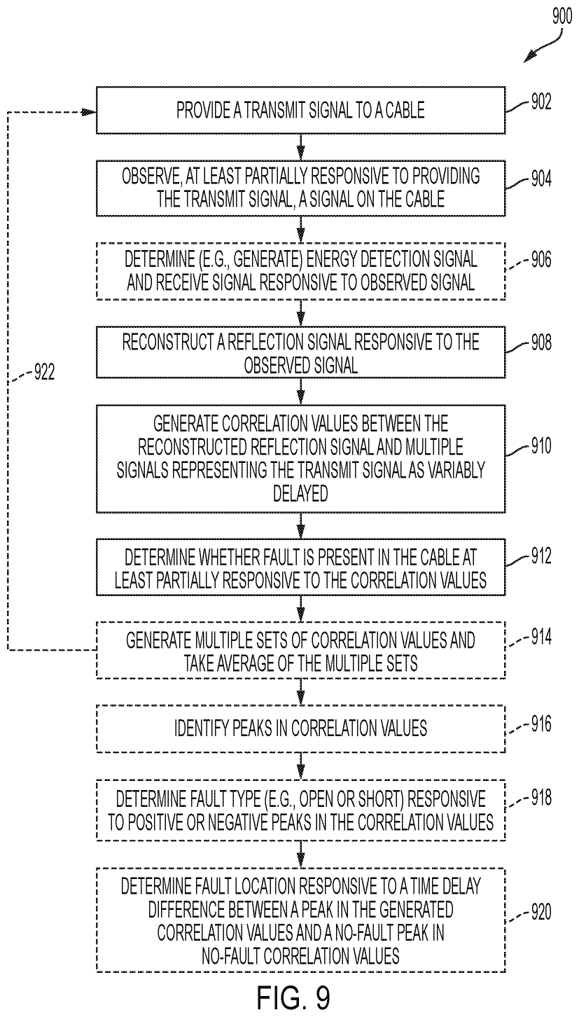

Processing circuitry 206 may also perform at least a portion or a totality of method 500 of FIG. 5 or method 900 of FIG. 9. In some examples, device 202 may be implemented within a processing circuit such as a microcontroller. In some examples, terminal 204 may be an integrated circuit device pin.

Processing circuitry 206 may generate correlation values representing the correlation between the reconstructed reflection signal and the transmit signal by determining multiple values of a magnitude of correlation between the reconstructed reflection signal and multiple signals representing the transmit signal as variably delayed. The generation of the correlation values including variably delaying the transmit signal is discussed in more detail with reference to method 500 of FIG. 5.

FIG. 3A is a plot 300a illustrating generation of a digital representation (e.g., RX signal 308) of an observed signal 302, in accordance with one or more examples. The plot 300a includes an analog sub-plot 310 illustrating an analog representation of the observed signal 302 and a digital sub-plot 312 illustrating the RX signal 308, which may be a digital representation of the observed signal 302, based on an upper RX threshold 304 and a lower RX threshold 306. In some examples the observed signal 302 may be the observed signal 214 observed on the cable 208, as discussed with reference to FIG. 2. In some examples the RX signal 308 may be a signal at an internal terminal of a processing circuitry (e.g., the processing circuitry 206 of FIG. 2, without limitation) used to analyze the observed signal 302. In some examples the RX signal 308 may be an array of sample values used by the processing circuitry. RX signal 308 may also sometimes be referred to as a “receive signal” in this disclosure.

The digital sub-plot 312 shows the RX signal 308, which represents the observed signal 302 as converted to a digital signal using a Schmitt trigger thresholder with the upper RX threshold 304 and the lower RX threshold 306. Using a Schmitt trigger may help reduce the effects of noise when converting the analog observed signal 302 to the digital RX signal 308.

Analog sub-plot 310 illustrates the upper RX threshold 304 and the lower RX threshold 306, according to one or more examples. When the amplitude of observed signal 302 rises above the upper RX threshold 304, the RX signal 308 is at a logic level high. When the amplitude of observed signal 302 drops below the lower RX threshold 306, the RX signal 308 is at a logic level low. RX signal 308 may be a 1-bit digital representation of analog observed signal 302. Generally, whenever the amplitude of observed signal 302 is positive, RX signal 308 is high and when the amplitude of observed signal 302 is negative, RX signal 308 is low.

FIG. 3B is a plot 300b illustrating generation of an ED signal 314 from the observed signal 302, in accordance with one or more examples. Similar to the plot 300a, the plot 300b includes an analog sub-plot 320 and a digital sub-plot 322. Similar to the analog sub-plot 310 of FIG. 3A, the analog sub-plot 320 illustrates the observed signal 302. In contrast to the analog sub-plot 310 of FIG. 3A, however, the analog sub-plot 320 includes an upper ED threshold 316 and a lower ED threshold 318, which are different from the upper RX threshold 304 and the lower RX threshold 306 of the analog sub-plot 310 of FIG. 3A. In contrast to the digital sub-plot 312 of FIG. 3A, which illustrates the RX signal 308, the digital sub-plot 322 illustrates the ED signal 314, which may be the ED signal 220 of FIG. 2. In some examples the ED signal 314 may be a signal at an internal terminal of a processing circuitry (e.g., the processing circuitry 206 of FIG. 2, without limitation) used to analyze the ED signal 314. In some examples the ED signal 314 may be an array of sample values used by the processing circuitry. ED signal 314 may be used to detect positive or negative energy on cable 208 upon which observed signal 302 is observed. The ED signal 314 may be a logic level high responsive to the amplitude of observed signal 302 rising above the upper ED threshold 316 or descending below the lower ED threshold 318. The ED signal 314 is low when the amplitude of observed signal 302 is between the upper ED threshold 316 and the lower ED threshold 318.

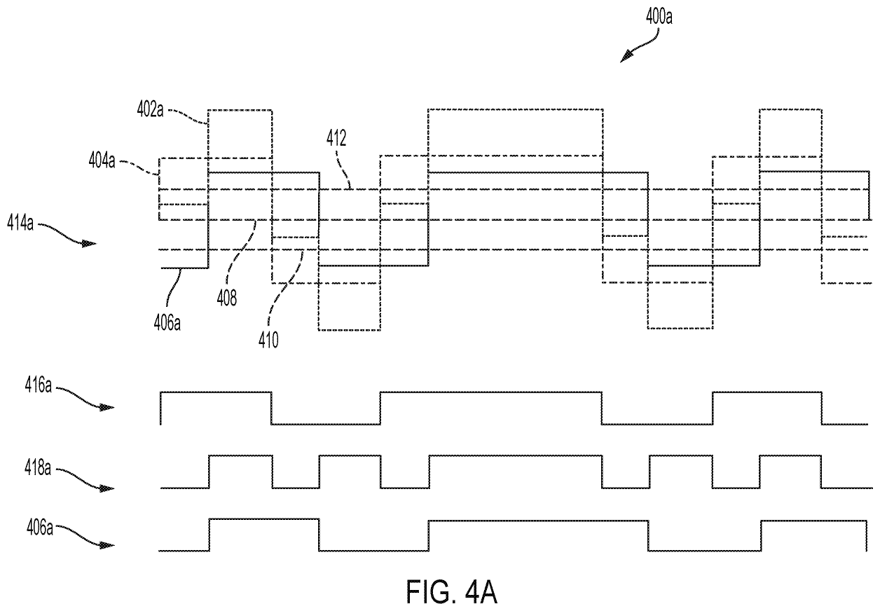

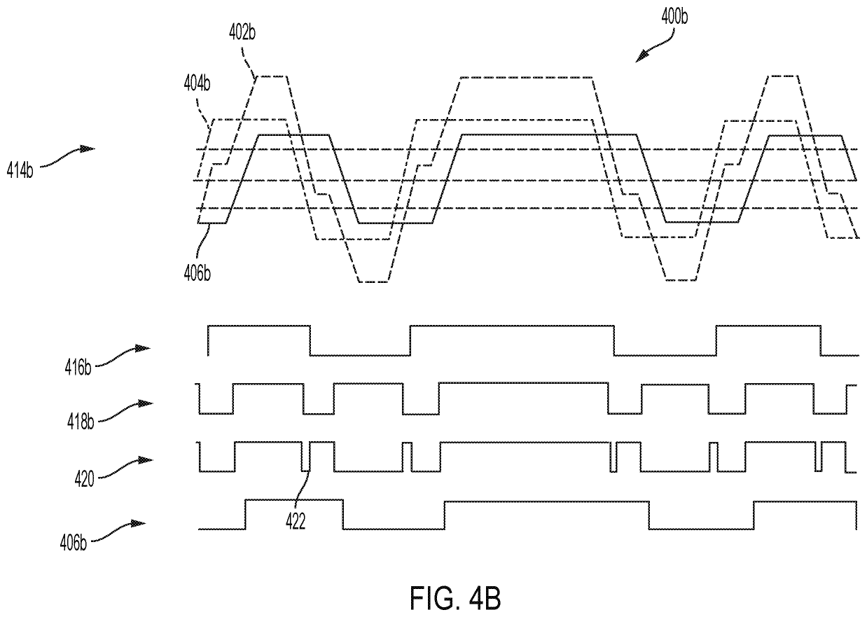

FIG. 4A is a signal timing diagram 400a illustrating an idealized example of a construction of a reflection signal, in accordance with some examples of the disclosure. Some signals illustrated in the signal timing diagram 400a are idealized because the signals transition between logic levels instantaneously, which may not occur in realistic implementations. Signal timing diagram 400a includes RX signal 416a, ED signal 418a, and reconstructed reflection signal 406a. The signal timing diagram 400a also includes a sub-diagram 414a including a composite view of transmit signal 404a, observed signal 402a, and reconstructed reflection signal 406a. Transmit signal 404a is transmitted on a cable (e.g., the cable 208 of FIG. 2) and observed signal 402a is received on the cable. Reconstructed reflection signal 406a is reconstructed based on RX signal 416a and ED signal 418a. As discussed with reference to FIG. 3A, the RX signal 308 is a digital representation, based on an upper RX threshold 304 and a lower RX threshold 306, of the observed signal 302. Similarly, the RX signal 416a is a digital representation of observed signal 402a, but based on a single RX threshold 408. RX signal 416a is high when observed signal 402a rises above RX threshold 408 and is low when observed signal 402a falls below RX threshold 408. As discussed with reference to FIG. 3B, the ED signal 314 is a digital representation, based on an upper ED threshold 316 and a lower ED threshold 318, of the observed signal 302. Similarly, ED signal 418a is high when observed signal 402a rises above the upper ED threshold 412 and is also high when observed signal 402a falls below lower ED threshold 410. ED signal 418a is low responsive to observed signal 402a being between upper ED threshold 412 and lower ED threshold 410.

In some examples, reconstructed reflection signal 406a is equal to ED when RX signal 416a is high, and is equal to (−ED) when RX signal 416a is low. Reconstructed reflection signal 406a may be used to determine whether a fault is present on the cable, as described more fully with reference to FIG. 5. Signal timing diagram 400a is an example of an open fault on the cable due to a positive correlation between the transmit signal 404a and reconstructed reflection signal 406a. The transmit signal 404a and the reconstructed reflection signal 406a are positively correlated because they exhibit a same polarity more often than not. In examples where a short fault is indicated (not shown), a negative correlation between the transmit signal 404a and the reconstructed reflection signal 406a is exhibited. A negative correlation means that the polarity of the transmit signal 404a is opposite the polarity of the reconstructed reflection signal 406a more often than not.

FIG. 4B is a signal timing diagram 400b illustrating a more realistic example of a reconstruction of a reflection signal in real-world conditions, in accordance with some examples of the disclosure. The signal timing diagram 400b includes representations of RX signal 416b, ED signal 418b, reconstructed reflection signal 420, ideal reconstructed reflection signal 406b, and a sub-diagram 414b including a composite view of transmit signal 404b, observed signal 402b, and ideal reconstructed reflection signal 406b. Instead of immediate rising and falling edges, as shown in the idealized signals of FIG. 4A, FIG. 4B shows an example of rising and falling edges that rise and fall more gradually over time, which is more realistic.

Due to the less-than-ideal conditions in which the reconstructed reflection signal 420 is reconstructed, imperfections or glitches such as a glitch 422 may be included as part of reconstructed reflection signal 420. Due to the prevalence of glitches in reconstructed reflection signal 420, noise may be introduced into a correlation between transmit signal 404b and reconstructed reflection signal 420. To reduce the effects of noise, the correlation between transmit signal 404b and reconstructed reflection signal 420 may be performed multiple times (e.g., multiple correlation signals may be averaged to reduce effects of noise).

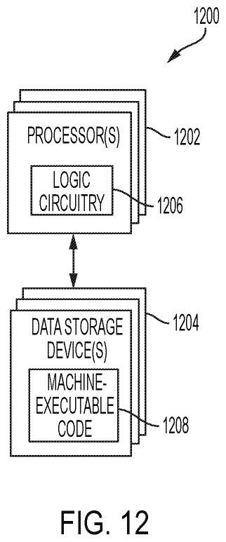

FIG. 5 is a flowchart depicting an example method 500 of detecting faults in a cable, in accordance with some disclosed examples. Method 500 may be performed, in some examples, by a circuit, a device, or a system, such as device 1200 of FIG. 12, and/or system 200 of FIG. 2. Inputs to method 500 may include reconstructed reflection signal 502 and transmit signal 504. Transmit signal 504 may correspond to any transmit signal described herein, including transmit signal 404a and 404b. At delay control 506, transmit signal 504 may be delayed by a specified amount of time. The delay time introduced by delay control 506 for transmit signal 504 may be controllably shifted from a minimum delay time (e.g., zero or no delay) to a maximum delay time (e.g., the amount of time for a transmit signal to reach its destination). By way of non-limiting example, the delay may be swept from the minimum delay time to the maximum delay time.

At correlation calculation 508, reconstructed reflection signal 502 and a delayed version of transmit signal 504 may be compared to determine the amount of correlation between the two signals, if any. Correlation calculation 508 may be implemented in any known fashion. One possible implementation for the correlation calculation 508, without limitation, is to oversample the reconstructed reflection signal 502. Oversampling the reconstructed reflection signal 502 may include sampling the reconstructed reflection signal 502 at a sampling frequency significantly higher than the Nyquist rate, which is defined as twice the bandwidth of the signal. Oversampling may help to improve resolution and signal-to-noise ratio, and can help in avoiding aliasing and phase distortion. The oversampled reconstructed reflection signal 502 may then be correlated with known transmit signal 504. In some examples the correlation calculation 508 may include performing an XOR operation on the reconstructed reflection signal 502 and transmit signal 504. In some examples the correlation calculation 508 may include a covariance calculation. In some examples the correlation calculation 508 may include convolution, cross-correlation, or autocorrelation calculations. In certain examples, correlation calculation 508 may refer to a visual correlation or a correlation that is determined by means other than strictly a mathematical calculation.

Method 500 may return to delay control 506 to try a different delay time for transmit signal 504. The process of delaying, calculating a correlation, changing the delay, and calculating a correlation may be repeated several times until the maximum delay time is reached (e.g., from the minimum delay to the maximum delay, constituting a “sweep”). The number of delays to test and the amount of time to delay in each delay test may be predetermined. Data obtained as a result of the correlation calculations may be stored in memory, such as storage 1204 of FIG. 12.

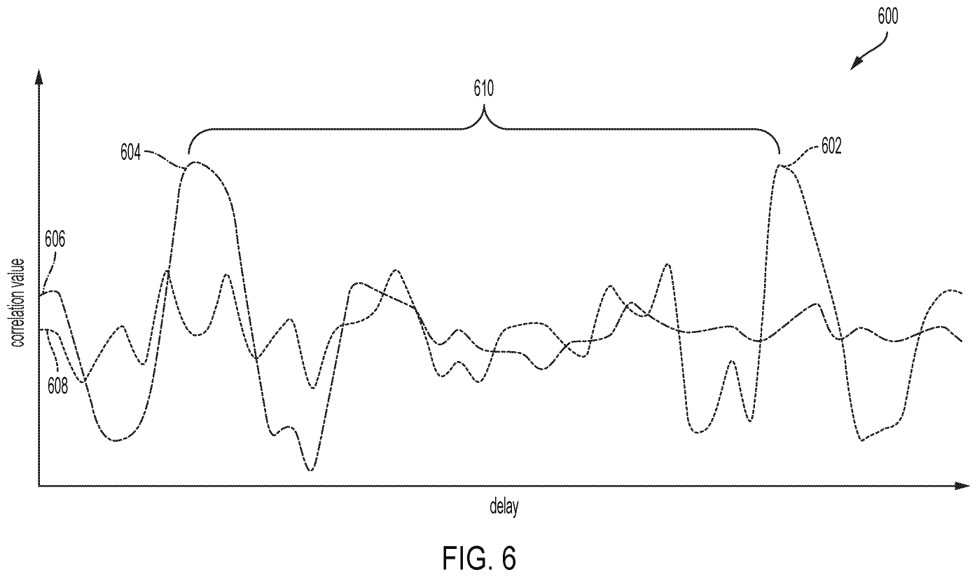

Method 500 may identify 510 a correlation peak responsive to results of the correlation calculation 508. A correlation peak occurs when the transmit signal 504 at a particular delay is similar to a reconstructed reflection signal 502. Once a peak is identified at identify correlation peak 510, method 500 may proceed to determine 512 a fault type and/or location responsive to the identified peak. An example of a method and manner in which a fault type or location may be determined is explained more fully in relation to FIG. 6.

FIG. 6 is a signal correlation plot 600 graphically illustrating a positive correlation between a transmit signal and a reconstructed reflection signal, in accordance with one or more examples. The horizontal axis of the signal correlation plot 600 represents delay of transmit signal 504 (FIG. 5) while the vertical axis represents magnitude of correlation between reconstructed reflection signal 502 (FIG. 5) and transmit signal 504. As delay control 506 (FIG. 5) of method 500 sweeps the variable delay from minimum delay to maximum delay, a value for the magnitude of the correlation between the transmit signal 504 and the reconstructed reflection signal 502 at that respective delay is stored in memory. Signal correlation plot 600 includes no-fault correlation curve 606 and open-fault correlation curve 608. No-fault correlation curve 606 may represent a set of correlation values that is expected when the cable, such as cable 208 of FIG. 2, does not have any faults. This no-fault correlation curve 606 may be stored in memory and used to assist in determining location of faults during testing. By way of non-limiting example, the no-fault correlation curve 606 may be generated during a test when it is known that there are no faults in the tested cable.

Each curve (e.g., no-fault correlation curve 606 and open-fault correlation curve 608) shown in signal correlation plot 600 may be generated by processing circuitry 206 of FIG. 2 and each curve shown includes a peak. The no-fault peak 604 is a peak in the no-fault correlation curve 606. No fault may be detected where a peak in the magnitude of the correlation between the transmit signal 504 and the reconstructed reflection signal 502 occurs at the same delay as the no-fault peak 604, or the same within a predetermined tolerance. Information including the no-fault peak 604 may be stored in memory such that the no-fault peak 604 may be compared to peaks in the magnitude of the correlation between the transmit signal 504 and the reconstructed reflection signal 502 that may indicate faults in the cable. For example, positive peak 602 may correspond to the open-fault correlation curve 608 and may indicate an open-circuit fault in the cable. A positive peak such as positive peak 602 may occur when features of the delayed transmit signal and the reconstructed reflection signal are in phase, which results in a positive correlation. A positive correlation, correlating with a positive peak in the correlation curve such as the positive peak 602, may indicate an open-circuit fault type.

A fault location may be determined by examining the horizontal graphical distance (e.g., a representative time) between no-fault peak 604 and a peak indicating a fault, such as positive peak 602. Because transmit signal 504 is known, and the delay corresponding to no-fault peak 604 is known, the difference in delay between no-fault peak 604 and positive peak 602 may be calculated. Using this difference in delay, the distance between the transmitter and the fault may be calculated. An example of this difference between no-fault peak 604 and positive peak 602 is noted in FIG. 6 as correlation peak difference 610.

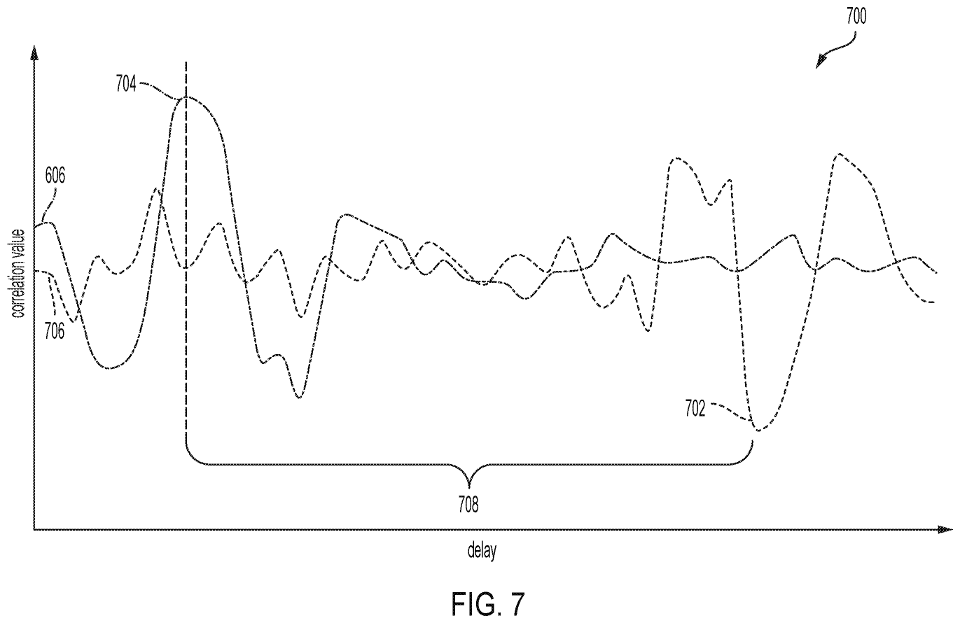

FIG. 7 is a signal correlation plot 700 that illustrates a negative correlation indicating a short-circuit fault, in accordance with one or more examples. Like signal correlation plot 600 in FIG. 6, the horizontal axis of the signal correlation plot 700 represents delay of transmit signal 504 (FIG. 5) while the y-axis represents magnitude of correlation between reconstructed reflection signal 502 (FIG. 5) and transmit signal 504. Signal correlation plot 700 includes the no-fault correlation curve 606 of FIG. 6 and a short-fault correlation curve 706.

Negative peak 702 of short-fault correlation curve 706 may indicate a short-circuit fault in the cable. A negative peak such as negative peak 702 may occur when the transmit signal and the reconstructed reflection signal are in phase, which may result in a negative correlation. Since a short-fault may cause a sign of the reconstructed reflection signal to be opposite that of the transmit signal, a peak in the short-fault correlation may be negative. A negative correlation, or a negative peak in the correlation signal, may indicate a short-circuit fault type.

A fault location may be determined in a similar manner as that explained in FIG. 6. For example, correlation peak difference 708 may correspond to a horizontal graphical difference between no-fault peak 704 and negative peak 702. This difference in delay time may be calculated and used to determine the location of the short fault.

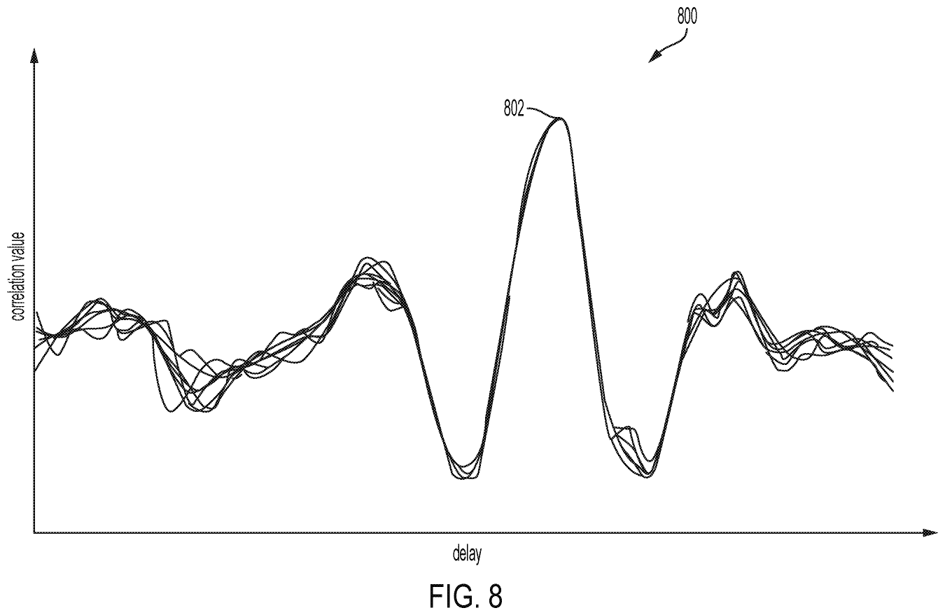

FIG. 8 is a signal correlation plot 800 depicting results of performing a correlation multiple times, in accordance with one or more examples. Performing the correlation (i.e., generating correlation values) more than once may help to reduce the effects of noise that are introduced by glitches and imperfections in a reconstructed reflection signal. For example, the delay for the transmit signal 504 (FIG. 5) may be repeatedly swept by the delay control 506 (FIG. 5) multiple times in order to generate multiple sets of correlation values, from which average correlation values may be obtained. Noise in any one set of correlation values may be likely to cancel out with noise in other sets of correlation values when averaged over a large number of sets of correlation values.

Similar to signal correlation plot 600, the horizontal axis of signal correlation plot 800 represents delay and the vertical axis represents magnitude of correlation. After performing the correlation between a transmit signal 504 and a reconstructed reflection signal 502 several times, average peak 802 becomes more defined.

FIG. 9 is a flowchart illustrating a method 900 for determining whether a fault is present on a cable, in accordance with one or more examples. In some examples, method 900 may be performed by a device or system, such as device 1200 or system 200.

At operation 902, a transmit signal is provided at a cable. At operation 904, a signal on the cable is observed, at least partially responsive to providing the transmit signal. The transmit signal may have reflected back to the signal transmitter due to an imperfection or discontinuity in the cable. The transmit signal may have reached its destination and returned back to the transmitter, which would be indicative of a lack of faults in the cable.

At optional operation 906, an ED signal and a receive signal may be determined responsive to the signal observed at operation 904. In some examples, determining an energy detection signal may include generating an array of energy detection values and in other examples, it may include sampling an energy detection terminal, connection, or pin. Similarly, determining a receive signal may include generating an array of receive values or sampling a receive terminal, connection, or pin (e.g., an RX pin). A receive signal determined in operation 906 may also be known as an RX signal. At operation 908, a reflection signal is reconstructed responsive to the observed signal. In some examples the reconstruction may be based, at least in part, on an RX signal and an ED signal derived from the observed signal (e.g., as determined in operation 906).

At operation 910, correlation values may be generated representing a correlation between the reconstructed reflection signal and multiple signals representing the transmit signal as variably delayed. The transmit signal as variably delayed may be the output of the delay control 506, where the transmit signal is repeatedly delayed by differing (i.e., incrementally increasing) amounts of time. The delay may be swept from a minimum delay to a maximum delay. The variably delayed transmit signals may be repeatedly compared to the reconstructed reflection signal, whereupon a value of correlation is generated for each comparison. Several values of correlation may be generated based on the multiple delayed transmit signals. In some examples, a correlation curve may be generated as a function of the correlation values over delay.

At operation 912, a fault may be determined at least partially responsive to the correlation values generated in operation 910. This process of providing a transmit signal, observing a signal, reconstructing a reflection signal, and determining the existence of a fault due to a correlation between the transmit signal and the reconstructed reflection signal may be repeated multiple times to generate multiple sets of further correlation values. An average of the multiple sets of correlation values, including the further correlation values, may be taken, as illustrated by optional operation 914. In some examples this average of correlations may be a moving average that may be updated each subsequent iteration. In the case of a moving average, optional path 922 may be taken so that an average might be taken, computed, and updated each iteration.

At optional operation 916, peaks in the correlation values, whether it be a single set of correlation values or the average of the multiple sets of further correlation values, may be identified. A peak may be a maximum value of a set of correlation values representing the correlation between the reconstructed reflection signal and the transmit signal, and may be negative or positive. At optional operation 918, a fault type may be determined responsive to the positive or negative peaks identified in operation 916. If the identified peak is positive, the fault type may be determined to be “open.” If the identified peak is negative, the fault type may be determined as “short.”

At optional operation 920, a fault location may be determined responsive to a time between a peak in the generated correlation values and a no-fault peak in a set of correlation values that represent a scenario where faults are known to be absent, which may be known as no-fault correlation values. The no-fault correlation values may be determined as a control set of values to which the generated set of correlation values including a peak may be compared in order to determine fault locations. If it is known that no faults exist for the no-fault correlation values, then it may be determined where a fault exists on the cable by measuring a difference in time delay between the no-fault peak and the peak in the test set of correlation values. The distance between the peaks may be determined if the speed of the signal propagation and the time between the peaks is known as distance is a function of speed and time, and may be determined by using a look up table (LUT) containing associations between fault location and time delay between peaks.

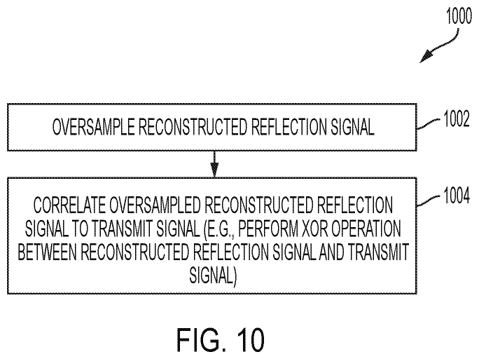

FIG. 10 is a flowchart illustrating a method 1000 of correlation. Method 1000 may correspond to the correlation that is completed at operation 910 of method 900. At operation 1002, a reconstructed reflection signal may be oversampled. At operation 1004, the oversampled reconstructed signal of operation 1002 may be correlated to the transmit signal to determine the signals' similarity. In some examples, the correlation may be done by performing an XOR operation between the reconstructed reflection signal and the transmit signal.

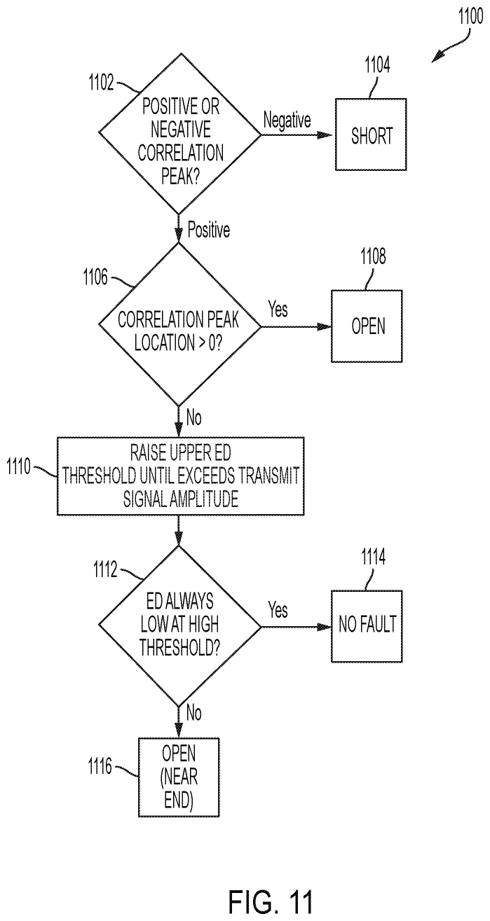

FIG. 11 depicts a flowchart of method 1100 of detecting a fault type and location, including faults at zero meters from a transmitter of a signal, according to some examples. The method 1100 may be performed by a device or system, such as device 1200 or system 200. In the case of a fault that exists in the cable immediately adjacent to the transmitter, the correlation peak of the faulty cable will be the same as the correlation peak for the known no-fault case. This may make fault detection of faults at zero meters from the transmitter difficult to detect and diagnose. This disclosure contemplates, in some examples, completing a method such as method 1100 with every fault detection test to detect open faults adjacent to the transmitter.

At decision 1102, an identified correlation peak is determined to be either positive or negative. If the correlation peak is negative, method 1100 may proceed to operation 1104, which indicates that the fault is a short, whereupon method 1100 ceases. The location of the short may be determined using means provided by this disclosure. If the examined correlation peak from decision 1102 is positive, then it is determined that the alleged fault is open and method 1100 proceeds to decision 1106.

At decision 1106, a location of an alleged fault is determined. In some examples, the location may be determined in a manner such as that of operation 920 of FIG. 9. A LUT may be used to correlate reflection information with fault location, where the LUT contains associations between reflection timing and fault locations. If a determined location of the alleged open fault is greater than zero meters from the transmitter, then the fault may be registered as an open fault located away from the transmitter, including at a far end of the cable or anywhere between the far end and a near end of the cable. In this case, method 1100 proceeds to operation 1108, determining that an open-fault is present (e.g., at a location greater than zero meters from the transmitter), and finishes. If the location of the alleged open fault appears to be equal to zero meters from the transmitter, then method 500 proceeds to operation 1110 for additional calculations to determine whether an open fault has occurred adjacent to the transmitter or whether no fault exists on the cable.

At operation 1110, the upper ED threshold is raised until it exceeds the amplitude of the transmit signal. Since the amplitude of the transmit signal is known, the upper ED threshold may be assigned a value that is known to exceed the amplitude of the transmit signal. In some examples, the upper ED threshold may be compared in real time to the amplitude of the transmit signal and is raised by increments until the comparison yields a result of the upper ED threshold being higher than the transmit signal amplitude.

At operation 1110, the upper ED threshold for extracting ED (e.g., upper ED threshold 316) is raised until the upper ED threshold exceeds the transmit signal amplitude. At decision 1112, if the value of the ED signal is low with the upper ED threshold higher than the transmit signal amplitude, then there is no fault because this is the expected output of the value of the ED signal. Method 1100 proceeds to operation 1114 and no fault is registered. However, if the value of the ED signal is high when the upper ED threshold is higher than the transmit signal amplitude, then an open fault exists in the cable near the transmitter, and the location of the open fault is approximately zero meters from the transmitter. This is an unexpected result that is not possible in a properly functioning cable. The value of the ED signal (e.g., high or low) is based on comparing the transmit signal to the ED threshold. If the threshold is higher than the transmit signal amplitude, the value of the ED signal must be low in a properly-functioning cable with no faults. However, if the value of the ED signal is high, then a fault is determined. In this case, method 1100 proceeds to operation 1116 and a fault is determined to be an open fault and the location is determined to be at zero meters from the transmitter.

FIG. 12 is a block diagram of an example device 1200 that, in various examples, may be used to implement various functions, operations, acts, processes, and/or methods disclosed herein. Device 1200 includes one or more processors 1202 (sometimes referred to herein as “processors 1202”) operably coupled to one or more apparatuses such as data storage devices (sometimes referred to herein as “storage 1204”), without limitation. Storage 1204 includes machine-executable code 1208 stored thereon (e.g., stored on a computer-readable memory) and processors 1202 include logic circuitry 1206. Machine-executable code 1208 include information describing functional elements that may be implemented by (e.g., performed by) logic circuitry 1206. Logic circuitry 1206 is adapted to implement (e.g., perform) the functional elements described by machine-executable code 1208. Device 1200, when executing the functional elements described by machine-executable code 1208, should be considered as special purpose hardware for carrying out the functional elements disclosed herein. In various examples, processors 1202 may perform the functional elements described by machine-executable code 1208 sequentially, concurrently (e.g., on one or more different hardware platforms), or in one or more parallel process streams.

When implemented by logic circuitry 1206 of processors 1202, machine-executable code 1208 is to adapt processors 1202 to perform operations of examples disclosed herein. For example, machine-executable code 1208 may adapt processors 1202 to perform at least a portion or a totality of method 500 of FIG. 5, method 900 of FIG. 9, or method 1100 of FIG. 11. As another example, machine-executable code 1208 may adapt processors 1202 to perform at least a portion or a totality of the operations discussed for device 202 of FIG. 2, and more specifically for processing circuitry 206 of FIG. 2.

Processors 1202 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein. A general-purpose computer including a processor is considered a special-purpose computer while the general-purpose computer is to execute computing instructions (e.g., software code) related to examples of the present disclosure. It is noted that a general-purpose processor (may also be referred to herein as a host processor or simply a host) may be a microprocessor, but in the alternative, processors 1202 may include any conventional processor, controller, microcontroller, or state machine. Processors 1202 may also be implemented as a combination of computing devices, such as a combination of a DSP and a microprocessor, a plurality of microprocessors, one or more microprocessors in conjunction with a DSP core, or any other such configuration.

In various examples, storage 1204 includes volatile data storage (e.g., random-access memory (RAM)), non-volatile data storage (e.g., Flash memory, a hard disc drive, a solid state drive, erasable programmable read-only memory (EPROM), without limitation). In various examples, processors 1202 and storage 1204 may be implemented into a single device (e.g., a semiconductor device product, a system on chip (SOC), without limitation). In various examples, processors 1202 and storage 1204 may be implemented into separate devices.

In various examples, machine-executable code 1208 may include computer-readable instructions (e.g., software code, firmware code). By way of non-limiting example, the computer-readable instructions may be stored by storage 1204, accessed directly by processors 1202, and executed by processors 1202 using at least logic circuitry 1206. Also by way of non-limiting example, the computer-readable instructions may be stored on storage 1204, transmitted to a memory device (not shown) for execution, and executed by processors 1202 using at least logic circuitry 1206. Accordingly, in various examples, logic circuitry 1206 includes electrically configurable logic circuitry.

In various examples, machine-executable code 1208 may describe hardware (e.g., circuitry) to be implemented in logic circuitry 1206 to perform the functional elements. This hardware may be described at any of a variety of levels of abstraction, from low-level transistor layouts to high-level description languages. At a high-level of abstraction, a hardware description language (HDL) such as an Institute of Electrical and Electronics Engineers (IEEE) Standard hardware description language (HDL) may be used, without limitation. By way of non-limiting examples, VERILOG™, SYSTEMVERILOG™ or very large scale integration (VLSI) hardware description language (VHDL™) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of logic circuitry 1206 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in various examples, machine-executable code 1208 may include an HDL, an RTL, a GL description, a mask level description, other hardware description, or any combination thereof.

In examples where machine-executable code 1208 includes a hardware description (at any level of abstraction), a system (not shown, but including storage 1204) may implement the hardware description described by machine-executable code 1208. By way of non-limiting example, processors 1202 may include a programmable logic device (e.g., an FPGA or a PLC) and the logic circuitry 1206 may be electrically controlled to implement circuitry corresponding to the hardware description into logic circuitry 1206. Also by way of non-limiting example, logic circuitry 1206 may include hard-wired logic manufactured by a manufacturing system (not shown, but including storage 1204) according to the hardware description of machine-executable code 1208.

Regardless of whether machine-executable code 1208 includes computer-readable instructions or a hardware description, logic circuitry 1206 is adapted to perform the functional elements described by machine-executable code 1208 when implementing the functional elements of machine-executable code 1208. It is noted that although a hardware description may not directly describe functional elements, a hardware description indirectly describes functional elements that the hardware elements described by the hardware description are capable of performing.

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, etc.) of the computing system. In some examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting embodiments of the disclosure include:

Example 1: An apparatus, comprising: a terminal to observe, responsive to provision of a transmit signal to a cable, a signal on the cable; and a processing circuitry to: reconstruct a reflection signal at least partially responsive to the observed signal; generate correlation values between the reconstructed reflection signal and multiple signals representing the transmit signal as variably delayed; and determine whether a fault is present in the cable at least partially responsive to the correlation values.

Example 2: The apparatus according to Example 1, wherein the processing circuitry is to reconstruct the reflection signal at least partially responsive to: an energy detection signal generated responsive to the observed signal and a receive signal generated responsive to the observed signal.

Example 3: The apparatus according to any of Examples 1 and 2, wherein the processing circuitry is to: generate multiple sets of further correlation values, each of the multiple sets of further correlation values representing a correlation between the reconstructed reflection signal and multiple signals representing the transmit signal as variably delayed; and generate the correlation values based at least partially on an average of the multiple sets of further correlation values.

Example 4: The apparatus according to any of Examples 1 through 3, wherein the processing circuitry is to: determine a fault location responsive to a time between a peak in a correlation curve representing the correlation values and a no-fault peak in a no-fault correlation curve representing correlation values between a no-fault reconstructed reflection signal and multiple signals representing the transmit signal as variably delayed.

Example 5: The apparatus according to any of Examples 1 through 4, wherein the processing circuitry is to determine a fault type responsive to a maximum peak in the correlation values.

Example 6: The apparatus according to any of Examples 1 through 5, wherein the processing circuitry is to determine an open fault type responsive to the maximum peak being positive in the correlation values.

Example 7: The apparatus according to any of Examples 1 through 6, wherein the processing circuitry is to determine a short fault type responsive to the maximum peak being negative in the correlation values.

Example 8: The apparatus according to any of Examples 1 through 7, wherein the correlation values are generated by oversampling the reconstructed reflection signal and correlating the oversampled reconstructed reflection signal to multiple signals representing the transmit signal as variably delayed.

Example 9: The apparatus according to any of Examples 1 through 8, wherein generating the correlation values comprises performing an XOR operation between the reconstructed reflection signal and one of multiple signals representing the transmit signal as variably delayed.

Example 10: A method, comprising: providing a transmit signal to a cable; observing, at least partially responsive to providing the transmit signal, a signal on the cable; reconstructing a reflection signal responsive to the observed signal; generating correlation values between the reconstructed reflection signal and multiple signals representing the transmit signal as variably delayed; and determining whether a fault is present in the cable at least partially responsive to the generated correlation values.

Example 11: The method according to Example 10, comprising determining a fault location responsive to the generated correlation values.

Example 12: The method according to any of Examples 10 and 11, wherein reconstructing the reflection signal comprises: determining an energy detection signal responsive to the observed signal; and determining the reconstructed reflection signal responsive to the energy detection signal.

Example 13: The method according to any of Examples 10 through 12, wherein determining whether the fault is present comprises determining a value of the energy detection signal when a threshold for the energy detection signal is greater than an amplitude of the transmit signal.

Example 14: The method according to any of Examples 10 through 13, wherein determining whether a fault is present in the cable is at least partially responsive to multiple sets of generated correlation values.

Example 15: The method according to any of Examples 10 through 14, wherein generating the correlation values comprises oversampling the reconstructed reflection signal and correlating the oversampled reconstructed reflection signal to the multiple signals representing the transmit signal as variably delayed.

Example 16: The method according to any of Examples 10 through 15, wherein correlating the oversampled reconstructed reflection signal to the multiple signals representing the transmit signal as variably delayed comprises performing XOR operations between the reconstructed reflection signal and the multiple signals representing the transmit signal as variably delayed.

Example 17: The method according to any of Examples 10 through 16, wherein determining whether a fault is present in the cable comprises identifying a maximum peak in the correlation values.

Example 18: The method according to any of Examples 10 through 17, comprising determining a fault type responsive to the maximum peak in the correlation values.

Example 19: The method according to any of Examples 10 through 18, wherein the fault type is determined as an open fault responsive to the maximum peak being positive.

Example 20: The method according to any of Examples 10 through 19, wherein the fault type is determined as a short fault responsive to the maximum peak being negative.

Example 21: A non-transitory computer-readable storage medium, the computer-readable storage medium including instructions that when executed by a computer, cause the computer to: provide a transmit signal to a cable; observe, at least partially responsive to providing the transmit signal, a signal on the cable; reconstruct a reflection signal responsive to the observed signal; generate correlation values representing correlation between the reconstructed reflection signal and multiple signals representing the transmit signal as variably delayed; and determine whether a fault is present in the cable at least partially responsive to the generated correlation values.

Example 22: A computing apparatus comprising: a processor; and memory storing instructions that, when executed by the processor, cause the computing apparatus to: provide a transmit signal to a cable; observe, at least partially responsive to providing the transmit signal, a signal on the cable; reconstruct a reflection signal responsive to the observed signal; generate correlation values representing correlation between the reconstructed reflection signal and multiple signals representing the transmit signal as variably delayed; and determine whether a fault is present in the cable at least partially responsive to the generated correlation values.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure.

What is claimed is:

1. An apparatus, comprising:
a terminal to observe, responsive to provision of a transmit signal to a cable, a signal on the cable; and
a processing circuitry to:
reconstruct a reflection signal at least partially responsive to the observed signal;
generate correlation values between the reconstructed reflection signal and multiple signals representing the transmit signal as variably delayed; and
determine whether a fault is present in the cable at least partially responsive to the correlation values.

2. The apparatus of claim 1, wherein the processing circuitry is to reconstruct the reflection signal at least partially responsive to: an energy detection signal generated responsive to the observed signal and a receive signal generated responsive to the observed signal.

3. The apparatus of claim 1, wherein the processing circuitry is to:
generate multiple sets of further correlation values, each of the multiple sets of further correlation values representing a correlation between the reconstructed reflection signal and multiple signals representing the transmit signal as variably delayed; and
generate the correlation values based at least partially on an average of the multiple sets of further correlation values.

4. The apparatus of claim 1, wherein the processing circuitry is to:
determine a fault location responsive to a time between a peak in a correlation curve representing the correlation values and a no-fault peak in a no-fault correlation curve representing correlation values between a no-fault reconstructed reflection signal and multiple signals representing the transmit signal as variably delayed.

5. The apparatus of claim 1, wherein the processing circuitry is to determine a fault type responsive to a maximum peak in the correlation values.

6. The apparatus of claim 5, wherein the processing circuitry is to determine an open fault type responsive to the maximum peak being positive in the correlation values.

7. The apparatus of claim 5, wherein the processing circuitry is to determine a short fault type responsive to the maximum peak being negative in the correlation values.

8. The apparatus of claim 1, wherein the correlation values are generated by oversampling the reconstructed reflection signal and correlating the oversampled reconstructed reflection signal to multiple signals representing the transmit signal as variably delayed.

9. The apparatus of claim 1, wherein generating the correlation values comprises performing an XOR operation between the reconstructed reflection signal and one of multiple signals representing the transmit signal as variably delayed.

10. A method, comprising:
providing a transmit signal to a cable;
observing, at least partially responsive to providing the transmit signal, a signal on the cable;
reconstructing a reflection signal responsive to the observed signal;
generating correlation values between the reconstructed reflection signal and multiple signals representing the transmit signal as variably delayed; and
determining whether a fault is present in the cable at least partially responsive to the generated correlation values.

11. The method of claim 10, comprising determining a fault location responsive to the generated correlation values.

12. The method of claim 10, wherein reconstructing the reflection signal comprises:
determining an energy detection signal responsive to the observed signal; and
determining the reconstructed reflection signal responsive to the energy detection signal.

13. The method of claim 12, wherein determining whether the fault is present comprises determining a value of the energy detection signal when a threshold for the energy detection signal is greater than an amplitude of the transmit signal.

14. The method of claim 10, wherein determining whether a fault is present in the cable is at least partially responsive to multiple sets of generated correlation values.

15. The method of claim 10, wherein generating the correlation values comprises oversampling the reconstructed reflection signal and correlating the oversampled reconstructed reflection signal to the multiple signals representing the transmit signal as variably delayed.

16. The method of claim 15, wherein correlating the oversampled reconstructed reflection signal to the multiple signals representing the transmit signal as variably delayed comprises performing XOR operations between the reconstructed reflection signal and the multiple signals representing the transmit signal as variably delayed.

17. The method of claim 10, wherein determining whether a fault is present in the cable comprises identifying a maximum peak in the correlation values.

18. The method of claim 17, comprising determining a fault type responsive to the maximum peak in the correlation values.

19. The method of claim 18, wherein the fault type is determined as an open fault responsive to the maximum peak being positive.

20. The method of claim 18, wherein the fault type is determined as a short fault responsive to the maximum peak being negative.

21. A non-transitory computer-readable storage medium, the computer-readable storage medium including instructions that when executed by a computer, cause the computer to:
provide a transmit signal to a cable;
observe, at least partially responsive to providing the transmit signal, a signal on the cable;
reconstruct a reflection signal responsive to the observed signal;
generate correlation values representing correlation between the reconstructed reflection signal and multiple signals representing the transmit signal as variably delayed; and
determine whether a fault is present in the cable at least partially responsive to the generated correlation values.

22. A computing apparatus comprising:
a processor; and
memory storing instructions that, when executed by the processor, cause the computing apparatus to:
provide a transmit signal to a cable;
observe, at least partially responsive to providing the transmit signal, a signal on the cable;
reconstruct a reflection signal responsive to the observed signal;
generate correlation values representing correlation between the reconstructed reflection signal and multiple signals representing the transmit signal as variably delayed; and
determine whether a fault is present in the cable at least partially responsive to the generated correlation values.
